(19) United States
(12) Patent Application Publication
(10) Pub. No.: US 2005/0266790 A1
(43) Pub. Date: Dec. 1, 2005

(54) Air scoop cooler

(76) Inventor: Shih Yu-Lin, Taipei City (TW)

Correspondence Address: Keith Kline;PRO-TECHTOR INTERNATIONAL SERVICES, 20775 Norada Court, Saratoga, CA, 95070-3018, US

(21) Appl. No.: 10/969,831

(22) Filed: Oct. 20, 2004

(30) Foreign Application Priority Data
Jun. 1, 2004 (TW) 093115582

(51) Int. Cl. H05K 7/20

(52) U.S. Cl. 454/184

(57) ABSTRACT

The present invention relates to an air scoop cooler. The air scoop cooler comprises a hollow duct, an exhaust opening, which can install an exhaust fan, and an entry opening on the top of the duct. The duct comprises a pull, a pin, and a hook to attach and to couple easily with a chassis of computer. On the top of the duct also comprises a plurality of protrusions against the chassis to fix. The CPU including its radiator and part of the mainboard including its electronic devices can be covered in the duct. The duct isolate noise of the fan of the radiator of CPU, and the exhaust fan exhausts inside warm air so that the outside cool air will stream into the duct via the entry opening forming airflow convection. In this invention the convection in the air scoop cooler can efficiently dissipate heat from working CPU and other electronic devices covered in the duct outside the chassis to cool devices down, and also keep silent operation.

### BACKGROUND OF THE INVENTION

1. Field of the Invention

The present invention relates to an air scoop cooler of a computer or an electronics system, and especially to a duct integrated with a fan, which covers microprocessors and other electronic components or devices on mainboard. With two ends opening in chassis, fans of the air scoop cooler produce an active convection of air induction and exhaust to cool electronic components or devices, and the duct also reduces noise.

2. Description of the Related Art

Electronics industry develops and upgrades soon. Integrated circuits (ICs) are getting smaller and consume more power, and also produce much heat, especially some modern microprocessors like Central Processing Units (CPUs) in computer. Heat will decrease efficiencies of electronic components, damage or even make components burnout. In computer system, for example, ICs, chips, and other electronic components are integrated onto a printed circuit board or mainboard and installed in a closed chassis. These are all heat sources dissipating heat and increasing temperature in internal chassis.

Fans and radiators are most used to transfer heat in prior art. A radiator with fins is attached onto a heat dissipating electronic component to enlarge surface, and a fan makes active airflow to convect. This simple technique can transfer heat efficiently only when the environment temperature is much lower than heat source, and this cooling assembly or system can only decrease temperature of specific component. In closed chassis, the prior art only transfer heat out of component into the chassis, and after a period of working time, the whole temperature inside will arise and heat transferring efficiency get lower and lower. For further solution, some prior designs set fans on sides of chassis blowing air in and out, but limited in wires and components obstructing inside, the convection is still slow and efficiency raises only few. Besides, more fans mean more noises of motors or airflow. High frequency buzz makes users uncomfortable and interfere with usages. Meanwhile, more fans also mean consuming more power, more cost, even more heat.

The key point is making a convection to introduce outside cool air into chassis and take heat out away. From now on, a new apparatus and method with simple and reasonable assembly solving foregoing problems will be disclosed.

### SUMMARY OF THE INVENTION

Accordingly, the primary object of the present invention is to provide a duct, covering CPU and it's own cooling system, and other electronic devices of the mainboard in chassis, to reduce noise of fan cooler of CPU, and to produce active convection introducing airflow in and out of chassis decreasing temperature of CPU and other electronic devices. To achieve the object, the present invention provides air scoop cooling assembly. A duct, forming an air scoop, covers the mainboard and is attached on chassis. Part of electronic components on mainboard, like CPU or other highly heat dissipating components, are covered in the duct. A fan set in the side of the duct can blow airflow out. On the top of the duct comprises an opening entry for air flowing in. The duct comprises a pull, a pin, and a fastener, to be installed in a proper position in the chassis, and also comprises a plurality of protrusions against the chassis to fix.

The CPU and it's own cooling system, and other electronic devices on the mainboard are covered in the duct to isolate noise of fan cooler of CPU, and the fan of the duct exhausts inside high temperature air so that cool air outside chassis flows into the duct via the opening entry to cool down CPU and other electronic devices prompt.

Comparing with prior techniques of heat sink of CPU, a fan blows fins of a radiator attached to the CPU in the chassis transferring heat to environment to decrease temperature of the CPU. But, in most cases, the environment inside the chassis is almost closed, as heat of the CPU transferred into the environment, the whole temperature of the environment inside the chassis will be getting higher and higher. Because of low efficiency of air convection between inside and outside of the chassis, as time goes by, the efficiency of the radiator of the CPU is also getting lower and lower. In this present invention the whole single duct of the air scoop cooler covers the CPU including its fan and part of electronic devices on mainboard. With the fan set in the side of the duct and the opening entry, the air scoop cooler creates convection in the chassis. The fan in this invention exhausts hot air from the inside of chassis and introduces outside cool air into the chassis to exchange. The duct forms an air scoop and air flow to convect inside.

The various objects and advantages of the present invention will be more readily understood from the following detailed description when read in conjunction with the appended drawings.

### BRIEF DESCRIPTION OF THE DRAWINGS

FIG. 1 illustrates a profile of an embodiment of this invention;

FIG. 2 illustrates a profile of an embodiment of this invention installed in the chassis;

FIG. 3 illustrates a profile of an embodiment of this invention with arrows indicating the direction of airflow.

### DETAILED DESCRIPTION OF THE INVENTION

In the following, various aspects of embodiments of this invention are described with figures for further details.

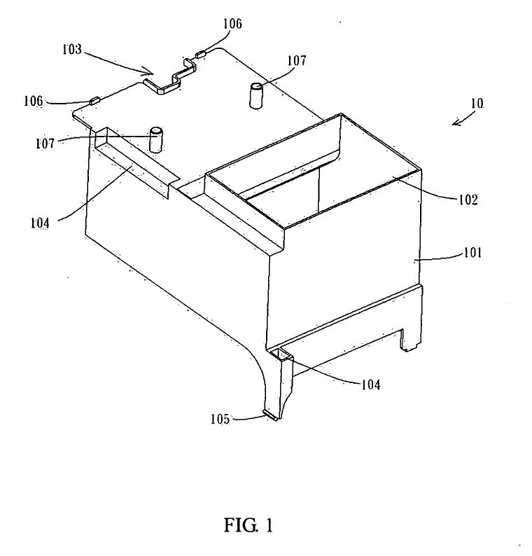

FIG. 1 is a profile of an embodiment of this invention. An air scoop cooler 10 comprises a duct 101, which is a single unit forming a hollow space. The said duck 101 comprises an exhaust opening 103 on side and an entry opening 102 on top side, so that airflow convect in the hollow space of the duct 101 via said two openings. The duct 101 also comprises a pull 104, a pin 105 and a hook 106, which are easy to be installed in relative positions of the chassis. The duct 101 further comprises a plurality of protrusions 107 to fix against the chassis.

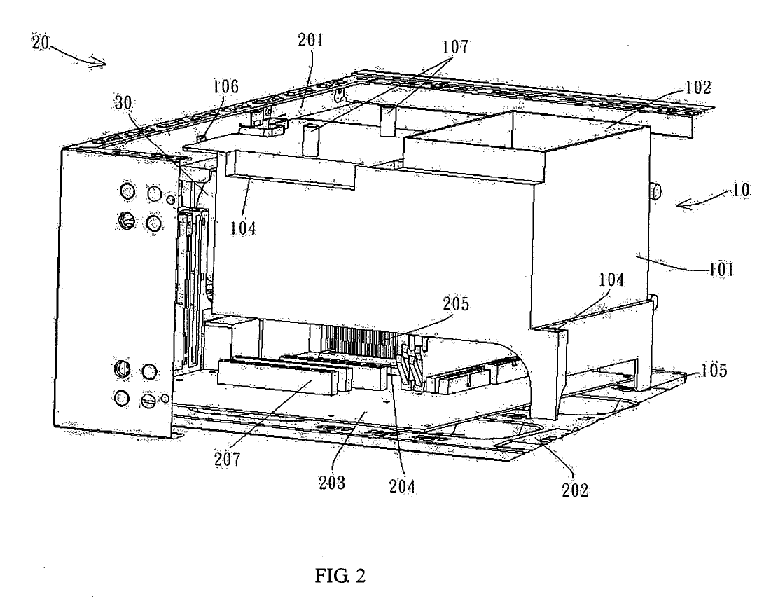

Referring to FIG. 2, in the situation of an embodiment of this invention illustrates a view of the complete air scoop cooler 10 attached in a computer chassis 20. In the prior art the CPU 204 in the chassis 20 is attached a radiator 205 and a fan to dissipate heat of the working CPU 204, and to avoid the CPU 204 overheating instability or even the CPU 204 burnout. As the electronic industry development, highly precision electronic devices can work at higher and higher clock speed (timing). But at the same time, electronic devices consume more power and also produce more heat. Sometimes under full load running, the surface temperature of a electronic device can be more than 100° C. The common techniques in prior arts are redesigning the radiator 205 to increase area of surface, utilizing new material, or enlarge the size and power of fan to enhance dissipating efficiency. The larger fan consumes more power that adds extra load of system power, and higher rotational speed fan also produces louder noise. In this invention the air scoop cooler is designed to fit normal computer chassis with no extra refit needed, or to enhance more efficiency, the design of the mainboard or the chassis can be changed in part.

As shown in FIG. 2, when the air scoop cooler 10 of this invention is installing inside the chassis 20, a user should only push the pull 104 of the duct 101 to put the pin 105 into a corresponding position of a side wall 202 of the chassis 20, and then push the duct 101 forward to fasten with a back wall 201 of the chassis 20. After installed, the protrusions 107 of the duct 101 will against the other side wall (not shown in the Fig.) to fix. A mainboard 203, and the CPU 204 including its cooler are part or totally covered in the air scoop cooler 10, so the noise of fan of the radiator 205 on the CPU 204 an be isolated. An exhaust fan 30 is also set at the exhaust opening 103.

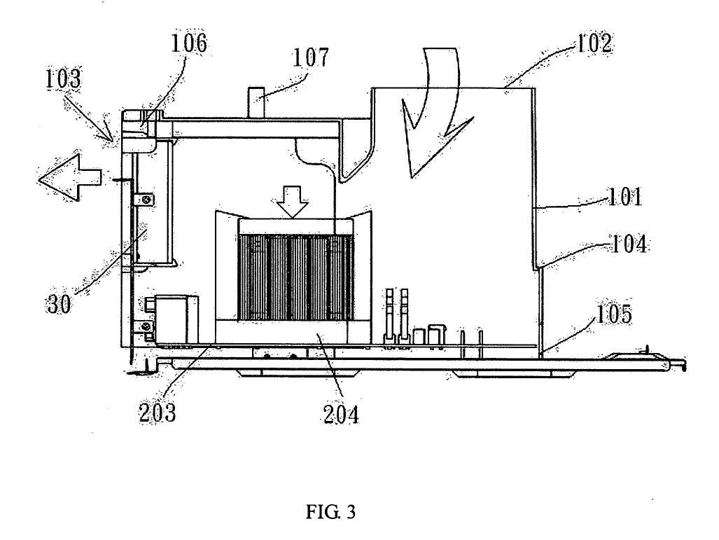

Referring to FIG. 3, it is a profile of an embodiment of this invention with arrows indicating the direction of airflow. As the duct 101 is installed in the chassis 20, the CPU 204 and the mainboard 203 are part or totally covered in the duct 101. The cooler of the CPU 204 blows cool air from the entry opening 102 to the CPU 204 and air get warm to take heat away. The warm air is blown into the duct 101, and the exhaust fan 30 exhausts warm air out, so that cool air outside the chassis 20 will stream into the duct 101 via the entry opening 102. Cool air stream via the entry opening 102 is directed onto the radiator 205 to cool down.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications intend to be embraced within the scope of the invention as defined in the appended claims.

1. An air scoop cooler, which is a unity duct in form, comprising an exhaust opening on one side, an entry opening no the top side, a pull, a pin, a hook and a plurality of protrusions, with fix and fasten in chassis by the pull, the pin, the hook and the protrusions, covering the mainboard in chassis to form a air-flowing space, and the two openings exchange air inside the chassis.

2. The air scoop cooler of claim 1, wherein a fan of proper size is installed at the exhaust opening.

3. The air scoop cooler of claim 2, wherein the fan is installed inside the air scoop cooler.
